(19) United States
(12) Patent Application Publication
(10) Pub. No.: US 2006/0105104 A1
(43) Pub. Date: May 18, 2006

(54) Method for introducing gas to treating apparatus having shower head portion

(76) Inventor: Kunihiro Tada, Yamanashi-Ken (JP)

Correspondence Address: SMITH, GAMBRELL & RUSSELL, LLP, 1850 M STREET, N.W., SUITE 800, WASHINGTON, DC, 20036, US

(21) Appl. No.: 10/514,149

(22) PCT Filed: May 16, 2003
(86) PCT No.: PCT/JP03/06158

§ 371 Date: Nov. 12, 2004

(30) Foreign Application Priority Data
May 17, 2002 (JP) 2002-143781

(51) Int. Cl. C23C 16/00

(52) U.S. Cl. 427/248.1

(57) ABSTRACT

The present invention is a method of introducing a gas into a processing unit, the processing unit including a processing container and a showerhead part, the processing container having a processing space for conducting a predetermined process to an object to be processed, the showerhead part having a plurality of separated diffusion rooms into each of which a source gas or a reduction gas is supplied, each of the diffusion rooms diffusing and supplying the supplied gas into the processing space. The method includes: a selecting step of selecting a combination wherein a pressure difference between a pressure of a diffusion room into which the reduction gas is supplied and a pressure of a diffusion room into which the source gas is supplied is larger, from combinations of the source gas, the reduction gas and the plurality of diffusion rooms, and a supplying step of supplying the respective gases into the respective diffusion rooms based on the combination selected at the selecting step.

### FIELD OF THE INVENTION

The present invention relates to a gas-introducing method used for a processing unit for depositing a thin film or the like onto a surface of an object to be processed such as a semiconductor wafer.

### DESCRIPTION OF THE RELATED ART

In general, a circuitry is often composed by a multilevel interconnection structure in a semiconductor device in response to a request for recent enhanced density and enhanced integration. In this case, a technique for filling a contact hole, which is a connection part between a lower-layer device and an upper-layer aluminum wiring, and a via hole, which is a connection part between a lower-layer aluminum wiring and an upper-layer aluminum wiring, is important to provide an electrical connection therebetween.

Aluminum and tungsten are generally used as the technique to fill the contact hole, the via hole and the like.

However, when the filling metal is formed directly onto a silicon layer which is a lower layer or an aluminum wiring, a diffusion layer formed in the silicon layer is destroyed by an attack of fluorine and/or an adhesiveness to an upper layer becomes worse, at a boundary portion therebetween. This is not preferable for the current semiconductor device, to which an electric-power saving and a high-speed operation are required.

Moreover, when tungsten is used for the filling, WF₆ gas which is one of process gases used in this process breaks into the Si substrate side so as to deteriorate electric properties and the like. This tendency is not preferable.

Consequently, in order to prevent the above phenomenon, before filling a contact hole, a through hole and the like with-the tungsten, a barrier metal layer is thinly formed all over the surface of a wafer including a surface inside the hole. A double-layer structure of Ti/TiN (titanium nitride) or a single-layer structure of TiN is generally used as a material of this barrier metal layer. Regarding prior arts, there are Japanese Patent Laid-Open Publication (Kokai) No. Hei-6-89873, Japanese Patent Laid-Open Publication (Kokai) No. Hei-10-106974, “Decomposition Property of Methylhydrazine with Titanium Nitridation at Low Temperature” (P. 934-938, J. Electrochem. Soc., Vol. 142 no. 3, March 1995), and so on.

A forming method of the Ti/TiN structure is explained. At first, a Ti film having a predetermined thickness is formed on a surface of a semiconductor wafer by using a TiCl₄ gas and a H₂ gas by means of a plasma CVD process. Then, in the same unit, under the plasma, a NH₃ gas (ammonia) is supplied, so that a surface of the Ti film is slightly and very thinly nitrided to form a TiN thin film.

Then, the semiconductor wafer is transferred from the plasma processing unit to a normal thermal CVD film-forming unit that doesn't have any plasma-generating mechanism. Then, by means of a thermal CVD process using a TiCl₄ gas and a NH₃ gas, a TiN film having a predetermined thickness is deposited onto the TiN thin film, so that a desired Ti/TiN structure is completed. If the TiN film is deposited by the thermal CVD process without forming the TiN thin film by nitridation of the Ti film, the lower Ti film may be etched by the TiCl₄ gas used in the thermal CVD process. Thus, in order to prevent the etching of the Ti film, the TiN thin film is formed at the above nitridation step.

Herein, the TiCl₄ gas and the NH₃ gas are easy to react on each other. The NH₃ gas, which is a reduction gas, easily reduces the TiCl₄ gas, which is a source gas, to easily form a TiN film. Thus, conventionally, as shown in FIG. 8, a plasma processing unit is provided with a showerhead part 98 having two diffusion rooms 100A and 100B that are separately formed in a vertical-tier manner. By means of the showerhead part 98, the TiCl₄ gas is supplied to form a Ti film at first, and then the NH₃ gas is supplied to nitride a surface of the Ti film. That is, the TiCl₄ gas and the NH₃ gas are supplied at different timings, respectively. That is, when the Ti film is formed, one gas such as the TiCl₄ gas is supplied into a processing container 104 via gas holes 102B communicated with the one diffusion room 100B. When the surface of the Ti film is nitrided, the other gas such as the NH₃ gas is supplied into the processing container 104 via gas holes 102A communicated with the other diffusion room 100A. Thus, the both gases never come into contact with each other in the showerhead part 98, so that reaction of the both gases, which may generate particles, is prevented.

As described above, in the conventional art, in order to prevent the contact reaction of the TiCl₄ gas and the NH₃ gas that may cause particle generation, the showerhead part 98 having the two independent diffusion rooms 100A and 100B is used.

However, even if the structure of the showerhead part 98 is adopted, when one gas is supplied into the processing space S, the one gas may flow back into the diffusion room 100A (or 100B) for the other gas through the gas holes 102A (or 102B) for ejecting the other gas. In the case, the one gas flowing into the diffusion room and the other gas staying in the diffusion room react on each other, which may generate an unnecessary TiN film. The unnecessary TiN film may fall off and generate particles.

### SUMMARY OF THE INVENTION

This invention is developed by focusing the aforementioned problems in order to resolve them effectively. An object of the present invention is to provide a method of introducing a gas into a processing unit, which can prevent a contact reaction of two gases that may cause particle generation in a showerhead part.

The inventors studied hard a mechanism of particle generation. Then, the inventors have found that back-diffusion of gas can be effectively inhibited when two gases are supplied under a condition wherein a pressure difference between two diffusion rooms is larger or wherein a conductance difference between the two diffusion rooms is smaller.

The present invention is a method of introducing a gas into a processing unit, the processing unit including a processing container and a showerhead part, the processing container having a processing space for conducting a predetermined process to an object to be processed, the showerhead part having a plurality of separated diffusion rooms into each of which a source gas or a reduction gas is supplied, each of the diffusion rooms diffusing and supplying the supplied gas into the processing space, the method comprising: a selecting step of selecting a combination wherein a pressure difference between a pressure of a diffusion room into which the reduction gas is supplied and a pressure of a diffusion room into which the source gas is supplied is larger, from combinations of the source gas, the reduction gas and the plurality of diffusion rooms; and a supplying step of supplying the respective gases into the respective diffusion rooms based on the combination selected at the selecting step.

According to the present invention, since a combination wherein a pressure difference between a pressure of a diffusion room into which the reduction gas is supplied and a pressure of a diffusion room into which the source gas is supplied is larger is selected from combinations of the source gas, the reduction gas and the plurality of diffusion rooms, it can be most effectively inhibited that one gas flows into a diffusion room for the other gas because of back-diffusion. Thus, any unnecessary reaction that may cause particle generation can be prevented. Therefore, particle generation can be inhibited.

Alternatively, the present invention is a method of introducing a gas into a processing unit, the processing unit including a processing container and a showerhead part, the processing container having a processing space for conducting a predetermined process to an object to be processed, the showerhead part having a plurality of separated diffusion rooms into each of which a source gas or a reduction gas is supplied, each of the diffusion rooms diffusing and supplying the supplied gas into the processing space, the method comprising: a selecting step of selecting a combination wherein a conductance difference between a conductance of a diffusion room into which the reduction gas is supplied and a conductance of a diffusion room into which the source gas is supplied is smaller, from combinations of the source gas, the reduction gas and the plurality of diffusion rooms; and a supplying step of supplying the respective gases into the respective diffusion rooms based on the combination selected at the selecting step.

According to the present invention, since a combination wherein a conductance difference between a conductance of a diffusion room into which the reduction gas is supplied and a conductance of a diffusion room into which the source gas is supplied is smaller is selected from combinations of the source gas, the reduction gas and the plurality of diffusion rooms, it can be most effectively inhibited that one gas flows into a diffusion room for the other gas because of back-diffusion. Thus, any unnecessary reaction that may cause particle generation can be prevented. Therefore, particle generation can be inhibited.

Preferably, the reduction gas and the source gas satisfy a characteristic wherein, in relationship between a flow rate of the source gas with respect to a certain amount of the reduction gas and a film-forming rate, the film-forming rate rises to a predetermined peak value, then rapidly falls and substantially saturates at that state as the flow rate of the source gas is increased.

In addition, preferably, the plurality of diffusion rooms are arranged in a two-tier manner in a vertical direction, and at the selecting step, a combination wherein the reduction gas is supplied into the upper diffusion room and the source gas is supplied into the lower diffusion room is selected.

For example, the source gas is a TiCl₄ gas, and the reduction gas is a NH₃ gas.

In addition, preferably, the source gas is adapted to be supplied into a diffusion room together with an inert gas, and the reduction gas is adapted to be supplied into a diffusion room together with a hydrogen gas.

### BRIEF DESCRIPTION OF THE DRAWINGS

FIG. 1 is a schematic cross sectional view showing a processing unit for carrying out a gas-introducing method according to the present invention;

FIG. 2 is a schematic cross sectional view of a showerhead part used in the processing unit of FIG. 1;

FIG. 3 is an enlarged sectional view showing a portion of gas-ejecting holes of the showerhead part;

FIG. 4 is a graph showing a film-forming rate when a flow rate of a TiCl₄ gas is changed, in a plasmaless normal thermal CVD process;

FIG. 5 shows process conditions and pressure differences between diffusion rooms, for the embodiment and for a conventional method, respectively;

FIGS. 6(A) and 6(B) are graphs showing densities of particles generated during sequential processes to 100 wafers, for the embodiment and for the conventional method, respectively;

FIGS. 7(A) and 7(B) are graphs showing change of number of particles with respect to the number of processed wafers; and

FIG. 8 is a schematic cross sectional view of a general showerhead part used in a plasma processing unit.

### DESCRIPTION OF THE PREFERRED EMBODIMENT

Hereinafter, an embodiment of a method of introducing a gas into a processing unit according to the present invention will be described in detail based on the attached drawings.

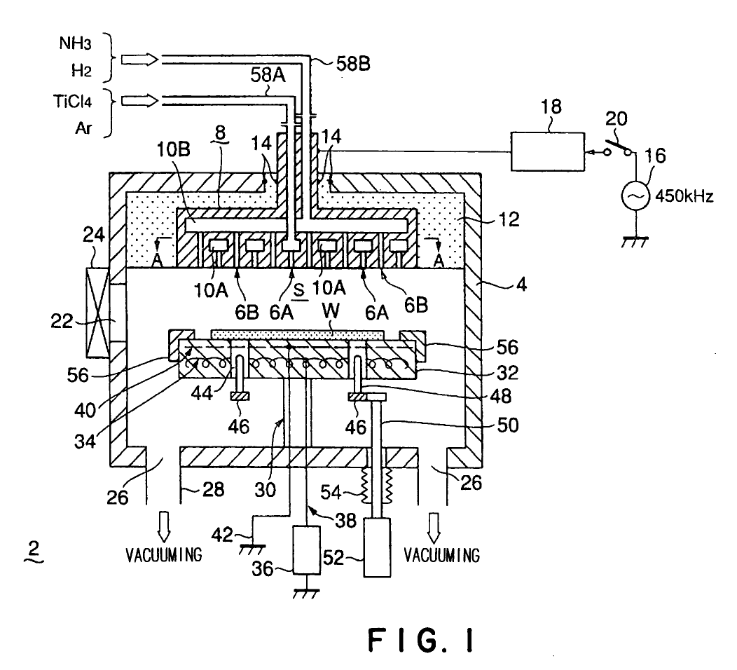

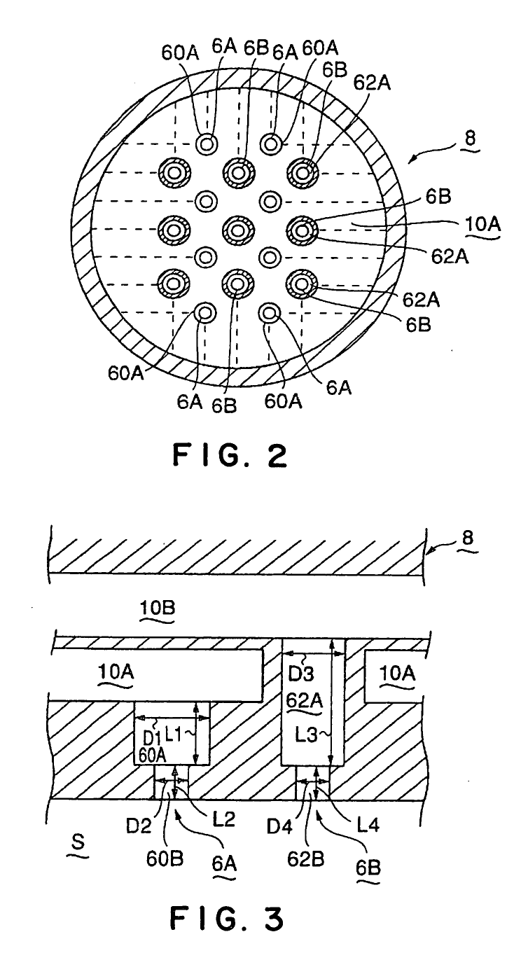

FIG. 1 is a schematic cross sectional view showing a processing unit for carrying out a gas-introducing method according to the present invention. FIG. 2 is a schematic cross sectional view of a showerhead part used in the processing unit of FIG. 1. FIG. 3 is an enlarged sectional view showing a portion of gas-ejecting holes of the showerhead part. Herein, a case is explained as an example, wherein the processing unit is a plasma CVD film-forming unit, a Ti film is formed as a metal film and then a surface of the Ti film is nitrided.

As shown in FIG. 1, the plasma CVD film-forming unit 2 as a processing unit has a processing container 4 formed cylindrically and made of, for example, aluminum, nickel or a nickel alloy. A ceiling part of the processing container 4 is provided with a showerhead part 8, which has a large number of gas-jetting holes (ways) 6A, 6B in a lower surface thereof. Thus, a process gas such as a film-forming gas or the like can be introduced into a processing space S in the processing container 4. For example two diffusion rooms 10A, 10B for diffusing the gas are defined separately in a vertical two-tier manner in the showerhead part 8. The gas jetting holes 6A, 6B are respectively communicated with the diffusion rooms 10A, 10B. Thus, the two gases are adapted to be first mixed in the processing space S. This manner of supplying the gases is called “post mix”. FIG. 2 shows a sectional view taken along an A-A line of FIG. 1. As shown in FIG. 2, the gas jetting holes 6A, 6B are provided in a substantially uniform distribution in the section.

The whole showerhead part 8 is made of an electric conductor such as aluminum, nickel or a nickel alloy and thus serves as an upper electrode. An outside peripheral surface and an upper surface of the showerhead part 8, which serves as the upper electrode, are entirely covered with an insulating member 12 such as quartz or alumina (Al₂O₃). The showerhead part 8 is fixed to the processing container 4 with an insulation state via the insulating member 12. In the case, sealing members 14 such as O-rings or the like are respectively interposed at connecting parts between the showerhead part 8, the insulating member 12 and the processing container 4. Thus, airtightness in the processing container 4 can be maintained.

Then, a high-frequency electric power source 16 that generates a high-frequency electric voltage of for example 450 kHz is connected to the showerhead part 8 via a matching circuit 18 and a open-close switch 20. Thus, when necessary, the high-frequency electric voltage is applied to the showerhead part 8, which is the upper electrode. The frequency of the high-frequency electric voltage is not limited to 450 kHz, but could be for example 13.56 MHz or the like.

In addition, a port 22, through which a wafer is conveyed, is formed at a lateral wall of the processing container 4. A gate valve 24 that can be opened and closed is provided at the port 22. A load-lock chamber or a transfer chamber or the like, not shown, can be connected to the gate valve 24.

An exhausting port 26 is provided at a bottom of the processing container 4. An exhausting pipe 28 is connected to the exhausting port 26, a vacuum pump or the like, not shown, being provided on the way of the exhausting pipe 28. Thus, when necessary, a vacuum can be created in the processing container 4. In the processing container 4, a stage 32, onto which a semiconductor wafer W as an object to be processed is placed, is provided via a column 30 from the bottom. The stage 32 serves as a lower electrode. Then, plasma can be generated by means of the high-frequency electric voltage in the processing space S between the stage 32 as the lower electrode and the showerhead part 8 as the upper electrode.

Specifically, the whole stage 32 is made of a ceramics such as AIN. A heater 34, which consists of for example a resistive element such as a molybdenum wire, is buried in the stage 32 in a predetermined pattern. A heater electric power source 36 is connected to the heater 34 via a wiring 38. Thus, if necessary, electric power can be supplied to the heater 34. In addition, an electrode body 40, which is for example a mesh of molybdenum wire, is buried in the stage 32 above the heater 34, so as to spread out in the whole in-plane (radial) directions of the stage 32. The electrode body 40 is grounded via a wiring 42. Herein, a high-frequency electric voltage as a bias voltage can be applied to the electric body 40.

A plurality of pin-holes 44 that extend through vertically are formed in the stage 32. A pushing-up pin 48 made of for example quartz, whose lower end is commonly connected to a connecting ring 46, is inserted in each pin-hole 44 in a freely movable manner. The connecting ring 46 is connected to an upper end of a protrudable rod 50, which extends through the bottom of the processing container in a vertically movable manner. The lower end of the protrudable rod 50 is connected to an air cylinder 52. Thus, each pushing-up pin 48 can protrude upward from an upper end of each pin-hole 44 and subside downward, when the wafer W is conveyed thereto or therefrom. An extendable bellows 54 is provided for a penetration part of the bottom of the processing container by the protrudable rod 50. Thus, the protrudable rod 50 can be vertically moved while maintaining the airtightness in the processing container 4.

A focus ring 56 is provided at a peripheral portion of the stage 32 as the lower electrode so as to concentrate the plasma into the processing container S. The gas pipes 58A, 58B are connected to the ceiling part of the showerhead part 8 so as to communicate with the diffusion rooms 10A, 10B, respectively.

A source gas and a reduction gas used for the film-forming process are respectively supplied into the diffusion rooms 10A and 10B, at the same timing or different timings.

Herein, it is important that a combination wherein (pressure in one diffusion room into which the reduction gas is supplied)−(pressure in the other diffusion room into which the source gas is supplied)=pressure difference P is larger is selected from combinations of the kinds of gases and the two diffusion rooms 10A, 10B, and that the respective gases are supplied based on the selected combination. Herein, a TiCl₄ gas is used as a source gas for forming a film, and a NH₃ gas or a H₂ gas is used as a reduction gas. From predetermined process conditions defining flow rates of the gases, if the value of the pressure difference P is larger when the TiCl₄ gas is supplied into the lower diffusion room 10A than when the TiCl₄ gas is supplied into the upper diffusion room 10B, the TiCl₄ gas is supplied into the lower diffusion room 10A. At that time, the other gas such as a NH₃ gas or a H₂ gas is supplied into the upper diffusion room 10B. Herein, the TiCl₄ gas is supplied together with a plasma gas such as an Ar gas, which can also serve as a carrier gas.

Then, based on FIG. 3, an example of detailed structure of the respective gas-jetting holes 6A and 6B is explained. The number of each of the gas-jetting holes 6A and 6B formed to be respectively communicated to the respective diffusion rooms 10A and 10B is around 570. The gas-jetting hole 6A communicated with the lower diffusion room 10A has a two-tier structure consisting of an upper gas hole 60A with a larger diameter and a lower gas hole 60B with a smaller diameter. In. addition, similarly, the gas-jetting hole 6B communicated with the upper diffusion room 10B has a two-tier structure consisting of an upper gas hole 62A with a larger diameter and a lower gas hole 62B with a smaller diameter.

Herein, the diameter D1 of the upper gas hole 60A of the gas-jetting hole 6A is set to 1.8 mm, the length L1 thereof is set to 7 mm, the diameter D2 of the lower gas hole 60B is set to 0.7 mm, and the length L2 thereof is set to 2 mm. In addition, the diameter D3 of the upper gas hole 62A of the gas-jetting hole 6B is set to 1.5 mm, the length L3 thereof is set to 21 mm, the diameter D4 of the lower gas hole 62B is set to 0.7 mm, and the length thereof L4 is set to 2 mm.

In addition, in the embodiment, a high-frequency electric power source 16 for generating plasma is provided. However, the present invention can be also applied to another processing unit for conducting a film-forming process by means of a thermal CVD process without using plasma. As a film-forming unit by means of the thermal CVD process, there is known a film-forming unit having a heating lamp, for example.

Next, a gas-introducing method of the present invention carried out by the above structured unit is explained.

Herein, in order to form a Ti film at first, the TiCl₄ gas as a source gas, the H₂ gas and the Ar gas are supplied. Then, in order to nitride a surface of the Ti film, the NH₃ gas as a reduction gas, the H₂ gas and the Ar gas are supplied.

As described above, as a supplying method of the TiCl₄ gas and the NH₃ gas into the showerhead part 8, there are two combinations. In the first combination, the TiCl₄ gas is supplied into the lower diffusion room 10A and the NH₃ gas is supplied into the upper diffusion room 10B. In the second combination, the TiCl₄ gas is supplied into the upper diffusion room 10B and the NH₃ gas is supplied into the lower diffusion room 10A.

In the embodiment, among the above two combinations, one combination is used wherein the above pressure difference P is larger. Taking into consideration the structure of the film-forming unit 2 and the process conditions such as the flow rates of the respective gases, the pressure difference P between the diffusion rooms is larger in the first combination than in the second combination. Thus, the first combination is selected. At that time, even if the gas diffuses back from the processing space S, reaction of the both gases, which may cause particle generation, is not generated.

At first, a semiconductor wafer W is introduced into the processing container 4 and placed on the stage 32. Then, the processing container 4 is sealed and the inside thereof is vacuumed. Then, the TiCl₄ gas as a source gas and the Ar gas as a plasma gas are supplied into the lower diffusion room 10A. The both gases diffuse in the diffusion room 10A, and are introduced into the processing space S via the gas-jetting holes 6A. At the same time, only the H₂ gas (not including NH₃ gas) as a film-forming gas is supplied into the upper diffusion room 10B. The H₂ gas diffuses in the diffusion room 10B, and is introduced into the processing space S via the gas-jetting holes 6B. Then, a high-frequency electric voltage of for example 450 kHz is applied between the showerhead part 8 as the upper electrode and the stage 32 as the lower electrode. Thus, a plasma is generated in the processing space S, so that the TiCl₄ gas is reduced and the Ti film (metal film) is formed on a surface of the wafer for a predetermined time.

In an example of process condition of the above case, a flow rate of the TiCl₄ gas is about 8 sccm, a flow rate of the Ar gas is about 1600 sccm, and a flow rate of the H₂ gas is about 4000 sccm. In addition, the process pressure of the processing space S is about 667 Pa (5 Torr). The process pressure of about 667 Pa is maintained not only at the film-forming step of the Ti film but also at the subsequent nitridation step of the Ti film.

After the Ti-film-forming step is conducted for a predetermined time as described above, the nitridation step of a surface of the Ti film is started continuously. In the nitridation step of a surface of the Ti film, the supply of the TiCl₄ gas is stopped, but the supply of the Ar gas is continued. In addition, the supply of the H₂ gas is also continued. Then, the supply of the NH₃ gas as a reduction gas is started. The NH₃ gas is supplied into the upper diffusion room 10B together with the H₂ gas, and introduced into the processing space S via the gas-jetting holes 6B. Then, a high-frequency electric voltage is applied between the showerhead part 8 and the stage 32. Thus, a plasma is generated in the processing space S, so that a surface of the Ti film reacts on active species in the NH₃ gas to be nitrided. As a result, a TiN film is thinly formed on the surface of the Ti film. In an example of process condition of the above case, a flow rate of the Ar gas is about 1600 sccm, a flow rate of the H₂ gas is about 2000 sccm, and a flow rate of the NH₃ gas is about 1500 sccm.

In both of the forming step of the Ti film and the nitridation step of the surface of the Ti film, the respective gases ejected from one of the gas-jetting holes 6A and 6B may diffuse back through the other of the gas-jetting holes 6A and 6B. If it is easy for the gases to diffuse back, a gas slightly remaining in a diffusion room and another gas diffusing back into the diffusion room may react on each other. That is, in the case, the TiCl₄ gas remains in one diffusion room 10A, and the NH₃ gas remains in the other diffusion room 10B. Thus, when the remaining gas reacts on another gas diffusing back into the diffusion room, an unnecessary TiN film may be deposited in the showerhead part 8, which may cause particle generation.

However, in the embodiment, as described above, the respective gases are supplied in such a manner that the pressure difference P is larger. Thus, generation of the above back-diffusion can be inhibited to the utmost, so that particle generation can be remarkably prevented.

Herein, an evaluation experiment for showing reduction of the number of particles was conducted. The evaluation result is explained.

At first, a film-forming rate by means of a plasmaless normal thermal CVD process was evaluated. Herein, the flow rate (supply amount) of the NH₃ gas was fixed to 400 sccm, while the flow rate (supply amount) of the TiCl₄ gas was changed within a range of 0 to 40 sccm. The process temperature was 650° C. and the process pressure was 660 Pa.

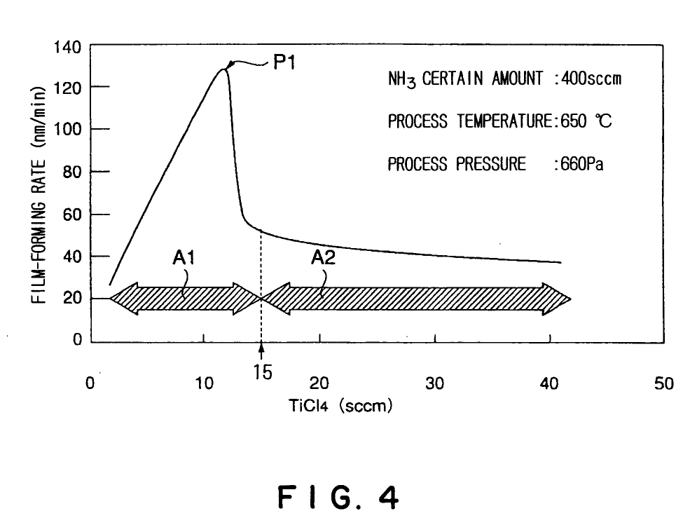

As clearly seen from the graph of FIG. 4, the film-forming rate was increased to a predetermined peak value P1 substantially linearly, as the flow rate of the TiCl₄ gas as a source gas was increased. On the other hand, after reaching the peak value P1, the film-forming rate rapidly falls and is maintained at the falling state (substantially saturates). That is, in a zone A1 wherein the flow rate of the TiCl₄ gas is small (0 to 15 sccm), NH₃ atmosphere is greatly overmuch. Thus, almost all the flow rate of the TiCl₄ gas is consumed to react on the NH₃ gas (state of rate-limiting by supply). To the contrary, in a zone A2 wherein the flow rate of the TiCl₄ gas is large (15 to 40 sccm), the atmosphere is overmuch of the TiCl₄ gas. Thus, the TiCl₄ gas doesn't react in a vapor phase but causes only a surface reaction depending on the temperature (state of rate-limiting by reaction).

From the result of FIG. 4, it has been found that it is difficult for TiN particles to be generated if the NH₃ gas diffuses in the TiCl₄ gas, but that it is easy for TiN particles to be generated if the TiCl₄ gas diffuses in the NH₃ gas because almost all the TiCl₄ gas can react on the NH₃ gas. Thus, it has been found that it is preferable in view of preventing particle generation to maintain the pressure in the diffusion room of the NH₃ gas higher than the pressure in the diffusion room of the TiCl₄ gas.

In addition, it is more preferable that (pressure in the diffusion room into which the NH₃ gas is supplied)−(pressure in the diffusion room into which the TiCl₄ gas is supplied)=pressure difference P is larger.

Next, in the unit explained with reference to FIGS. 1 to 3, under the above condition of the flow rates of the gases, a case (embodiment) wherein the TiCl₄ gas is supplied into the lower diffusion room 10A and a case (conventional method) wherein the TiCl₄ gas is supplied into the upper diffusion room 10B were evaluated. In addition, the film-forming unit used for the evaluation was a unit that can handle wafers of a 300 mm size.

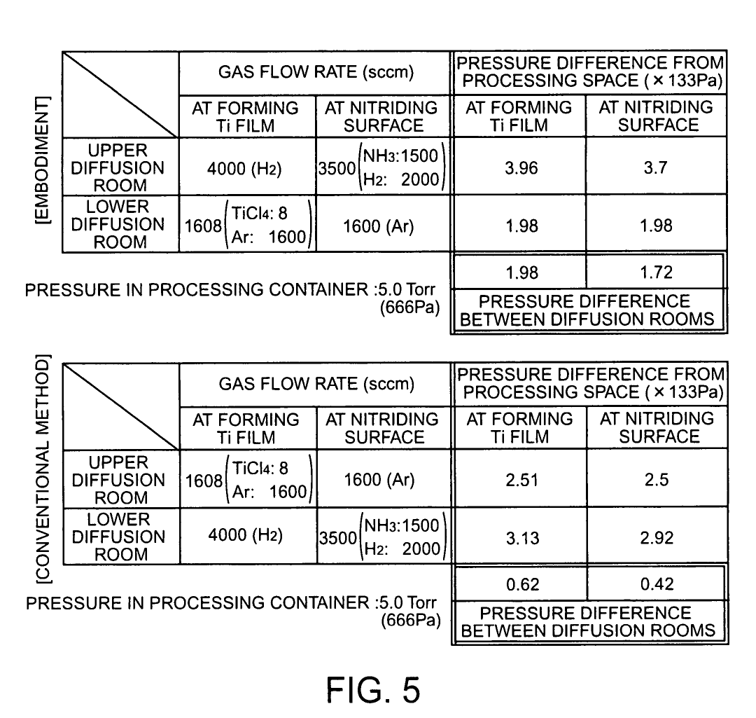

As shown in FIG. 5, as the case of the embodiment, the TiCl₄ gas was supplied into the lower diffusion room 10A (at forming a Ti film) and the NH₃ gas was supplied into the upper diffusion room 10B (at nitriding the surface). In the case, the pressure of the upper diffusion room 10B was 3.96×133 Pa at the forming step of the Ti film, and 3.7×133 Pa at the nitriding step of the surface. The pressure of the lower diffusion room 10A was 1.98×133 Pa at the forming step of the Ti film, and 1.98×133 Pa at the nitriding step of the surface. Thus, the value of the pressure difference P was 1.98×133 Pa at the forming step of the Ti film, and 1.72×133 Pa at the nitriding step of the surface.

To the contrary, as the case of the conventional method, the TiCl₄ gas was supplied into the upper diffusion room 10B (at forming a Ti film) and the NH₃ gas was supplied into the lower diffusion room 10A (at nitriding the surface). In the case, the pressure of the upper diffusion room 10B was 2.51×133 Pa at the forming step of the Ti film, and 2.5×133 Pa at the nitriding step of the surface. The pressure of the lower diffusion room 10A was 3.13×133 Pa at the forming step of the Ti film, and 2.92×133 Pa at the nitriding step of the surface. Thus, the value of the pressure difference P was 0.62×133 Pa at the forming step of the Ti film, and 0.42×133 Pa at the nitriding step of the surface.

That is, the pressure difference between the diffusion rooms 10A and 10B in the embodiment was about three or four times as large as that in the conventional method.

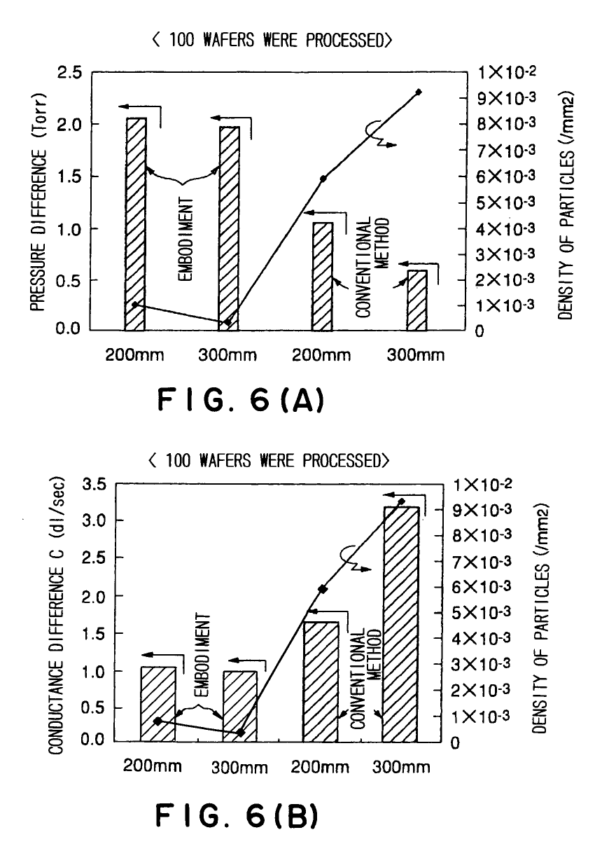

According to the above embodiment and the above conventional method, respectively, 100 wafers were sequentially processed. FIG. 6(A) shows graphs of densities of particles generated during the processes. In FIG. 6(A), the result of a similar experiment conducted by using a unit that can handle wafers of a 200 mm size is also shown. On the other hand, FIG. 6(B) shows graphs similar to FIG. 6(A), wherein conductance differences between the diffusion rooms are evaluated instead of the pressure differences P.

FIG. 6(A) shows a relationship between pressure differences P of the diffusion rooms and densities of the particles. FIG. 6(B) shows a relationship between conductance differences of the diffusion rooms and densities of the particles. Herein, the conductance difference C means that C=(conductance between the diffusion room into which the NH₃ gas is supplied and the processing container)−(conductance between the diffusion room into which the TiCl₄ gas is supplied and the processing container). Herein, for example, the value of the conductance between the diffusion room into which the NH₃ gas is supplied and the processing container is given by [gas flow rate flowing between the diffusion room into which the NH₃ gas is supplied and the processing container (I/s)]×[pressure in the processing container (Torr)]÷[pressure difference between the diffusion room into which the NH₃ gas is supplied and the processing container (Torr)]. As clearly seen from the graph of FIG. 6(B), the conductance difference C is smaller in the embodiment.

As shown in FIGS. 6(A) and 6 (B), both when the wafer size is 200 mm and 300 mm, the density of particles in the conventional method was about 6×10⁻³ to 9×10⁻³/mm², which is so large and thus not so good. To the contrary, in the embodiment, the density of particles was about 0 to 1×10⁻³/mm², which is so small and thus so good.

In addition, change of number of particles with respect to the number of processed wafers was evaluated, for the embodiment and for the conventional method, respectively. The evaluation result is explained.

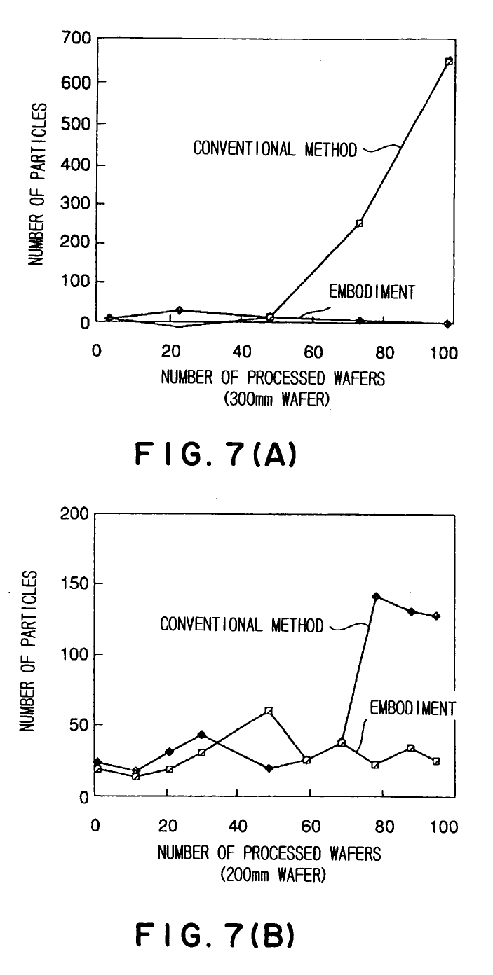

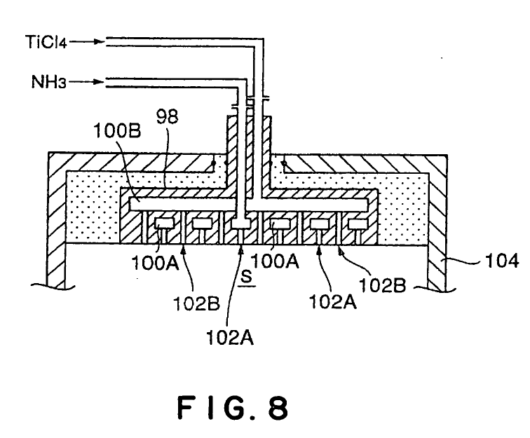

FIG. 7 is graphs showing the change of number of particles. FIG. 7(A) shows the result by the unit for the 300 mm wafer size, and FIG. 7(B) shows the result by the unit for the 200 mm wafer size.

As clearly seen from FIG. 7, both when the wafer size is 200 mm and 300 mm, in the embodiment, the number of particles was very small and thus good, independently on the number of processed wafer. On the other hand, in the conventional method, the number of particles was small before the number of processed wafers reached 50 (in the case of FIG. 7(A)) or 70 (in the case of FIG. 7(B)), but the number of particles was rapidly increased after the number of processed wafers overpassed the above value.

In addition, in the above embodiment, the TiCl₄ gas as a source gas is introduced into the lower diffusion room 10A, and the NH₃ gas as a reduction gas is introduced into the upper diffusion room 10B. However, the pressure difference P between the diffusion rooms 10A and 10B may change depending on the numbers and/or the sizes of the gas-jetting holes 6A and 6B, and/or the process conditions such as the flow rates of the above gases or other gases. That is, it is determined which diffusion room the source gas and/or the reduction gas are respectively introduced into, depending on the above conditions.

In addition, in the above embodiment, the supply timing of the TiCl₄ gas and the supply timing of the NH₃ gas are different. However, the present invention can be also applied to a case wherein the TiCl₄ gas and the NH₃ gas are simultaneously supplied to form a film, for example a TiN film by means of a thermal CVD process.

In addition, in the embodiment, for the purpose of easy understanding of the present invention, the structure of the showerhead part 8 having the two diffusion rooms 10A and 10B is explained. However, of course, the present invention can be applied to a showerhead part having three or more diffusion rooms.

In addition, in the above explanation, the Ti film is formed as a metal film, and then the surface of the Ti film is nitrided. However, this invention is not limited thereto, but applicable to a case for forming another metal film such as a W film or a Ta film and nitriding a surface of the metal film.

In addition, in the above embodiment, the semiconductor wafer is taken as an example of the object to be processed. However, this invention is not limited thereto, but applicable to cases for processing a glass substrate, an LCD substrate, and the like.

1. A method of introducing a gas into a processing unit, the processing unit including a processing container and a showerhead part, the processing container having a processing space for conducting a predetermined process to an object to be processed, the showerhead part having a plurality of separated diffusion rooms into each of which a source gas or a reduction gas is supplied, each of the diffusion rooms diffusing and supplying the supplied gas into the processing space, the method comprising:
a selecting step of selecting a combination wherein a pressure difference between a pressure of a diffusion room into which the reduction gas is supplied and a pressure of a diffusion room into which the source gas is supplied is larger, from combinations of the source gas, the reduction gas and the plurality of diffusion rooms, and
a supplying step of supplying the respective gases into the respective diffusion rooms based on the combination selected at the selecting step.

2. A method of introducing a gas into a processing unit, the processing unit including a processing container and a showerhead part, the processing container having a processing space for conducting a predetermined process to an object to be processed, the showerhead part having a plurality of separated diffusion rooms into each of which a source gas or a reduction gas is supplied, each of the diffusion rooms diffusing and supplying the supplied gas into the processing space, the method comprising:
a selecting step of selecting a combination wherein a conductance difference between a conductance of a diffusion room into which the reduction gas is supplied and a conductance of a diffusion room into which the source gas is supplied is smaller, from combinations of the source gas, the reduction gas and the plurality of diffusion rooms, and
a supplying step of supplying the respective gases into the respective diffusion rooms based on the combination selected at the selecting step.

3. A method according to claim 1, wherein
the reduction gas and the source gas satisfy a characteristic wherein, in relationship between a flow rate of the source gas with respect to a certain amount of the reduction gas and a film-forming rate, the film-forming rate rises to a predetermined peak value, then rapidly falls and substantially saturates at that state as the flow rate of the source gas is increased.

4. A method according to claim 1, wherein
the plurality of diffusion rooms are arranged in a two-tier manner in a vertical direction, and
at the selecting step, a combination wherein the reduction gas is supplied into the upper diffusion room and the source gas is supplied into the lower diffusion room is selected.

5. A method according to claim 1, wherein
the source gas is a TiCl₄ gas, and
the reduction gas is a NH₃ gas.

6. A method according to claim 1, wherein
the source gas is adapted to be supplied into the diffusion room together with an inert gas, and
the reduction gas is adapted to be supplied into the diffusion room together with a hydrogen gas.

7. A method according to claim 2, wherein
the reduction gas and the source gas satisfy a characteristic wherein, in relationship between a flow rate of the source gas with respect to a certain amount of the reduction gas and a film-forming rate, the film-forming rate rises to a predetermined peak value, then rapidly falls and substantially saturates at that state as the flow rate of the source gas is increased.

8. A method according to claim 2, wherein
the plurality of diffusion rooms are arranged in a two-tier manner in a vertical direction, and
at the selecting step, a combination wherein the reduction gas is supplied into the upper diffusion room and the source gas is supplied into the lower diffusion room is selected.

9. A method according to claim 2, wherein
the source gas is a TiCl₄ gas, and
the reduction gas is a NH₃ gas.

10. A method according to claim 2, wherein
the source gas is adapted to be supplied into the diffusion room together with an inert gas, and
the reduction gas is adapted to be supplied into the diffusion room together with a hydrogen gas.
